(19) United States
(12) Patent Application Publication
(10) Pub. No.: US 2006/0025955 A1
(43) Pub. Date: Feb. 2, 2006

(54) Gas density transducer

(76) Inventors: Anthony D. Kurtz, Saddle River, NJ (US); Wolf S. Landmann, Fair Lawn, NJ (US)

Correspondence Address: PLEVY & HOWARD, P.C., P.O. BOX 226, FORT WASHINGTON, PA, 19034, US

(21) Appl. No.: 11/007,681

(22) Filed: Dec. 8, 2004

Related U.S. Application Data
(60) Provisional application No. 60/592,175, filed on Jul. 29, 2004.

(51) Int. Cl. G01R 27/28

(52) U.S. Cl. 702/117

(57) ABSTRACT

A gas density transducer including: a piezoresistive bridge sensor operative to provide an output indicative of an applied pressure, a computing processor having multiple inputs and at least one output, with the output of the bridge sensor coupled to an input of the processor; a temperature sensor coupled to an input of the processor for providing at an output a signal indicative of a temperature of the bridge sensor, the output of the temperature sensor coupled to an input of the processor; and, at least one memory accessible by the processor and having stored therein: compensation coefficients for compensating the output of the bridge sensor for temperature variation; gas specific coefficients of the Van der Waal's equation; and, code for providing at an output of the processor a signal indicative of a gas density when the bridge is subjected to a gas containing environment.

### RELATED APPLICATIONS

This application claims priority of U.S. patent application Ser. No. 60/592,175, entitled GAS DENSITY TRANSDUCER, filed Jul. 29, 2004, the entire disclosure of which is hereby incorporated as if being set forth in its entirety herein.

### FIELD OF INVENTION

The present invention generally relates to a transducer apparatus, and more particularly, to a transducer apparatus which utilizes a microprocessor to determine gas density.

### BACKGROUND OF THE INVENTION

It is believed to be desirable to measure gas densities, such as gas densities within a pressurized tank. The present invention relates to a gas density transducer, or a transducer that produces an output indicative of, such as proportional to, a gas density to be measured.

### SUMMARY OF THE INVENTION

A gas density transducer comprising a piezoresistive bridge sensor operative to provide an output indicative of an applied pressure, a computing processor having multiple inputs and at least one output, with the output of the bridge sensor coupled to an input of the processor; a temperature sensor coupled to an input of the processor for providing at an output a signal indicative of a temperature of the bridge sensor, the output of the temperature sensor coupled to an input of the processor; and, at least one memory accessible by the processor and having stored therein: compensation coefficients for compensating the output of the bridge sensor for temperature variation; gas specific coefficients of the Van der Waal's equation; and, code for providing at an output of the processor a signal indicative of a gas density when the bridge is subjected to a gas containing environment.

### BRIEF DESCRIPTION OF THE FIGURES

Understanding of the present invention will be facilitated by consideration of the following detailed description of the preferred embodiments of the present invention taken in conjunction with the accompanying drawings, in which:

FIG. 1 depicts a schematic diagram of a gas density transducer according to an aspect of the present invention; and,

FIG. 2 depicts a block diagram of a process suitable for use with the transducer of FIG. 1 according to an aspect of the present invention.

### DETAILED DESCRIPTION OF THE PREFERRED EMBODIMENTS

It is to be understood that the figures and descriptions of the present invention have been simplified to illustrate elements that are relevant for a clear understanding of the present invention, while eliminating, for purposes of clarity, many other elements found in typical transducer systems and methods of making and using the same. Those of ordinary skill in the art will recognize that other elements are desirable and/or required in order to implement the present invention. However, because such elements are well known in the art, and because they do not facilitate a better understanding of the present invention, a discussion of such elements is not provided herein.

According to an aspect of the present invention, where the gas volume is constant or known, a transducer output is indicative of the mass of the gas. This measurement is useful for determining the amount of gas in a container, where continuous gas consumption occurs and it is desirable to know the amount of gas remaining in a container, for example. This type of transducer has a distinct advantage over a standard pressure transducer, as the pressure can change due to temperature variations, for example.

Other applications of such transducers include the detection of leaks in a gas tank from where no consumption is supposed to occur during normal conditions. This, for example, can be an emergency oxygen tank or nitrogen pressure tank to be used in case of hydraulic failure. In such cases, simple pressure measurements may not be satisfactory, due at least in part to temperature effects.

In general, detecting gas leaks using the Van der Waal equation is well known. Reference is made to U.S. Pat. No. 5,428,985 entitled, “Gas Leak Detection Apparatus and Methods” issued on Jul. 4, 1995 to A. D. Kurtz et al. and assigned to Kulite Semiconductor Products, Inc., the assignee herein. This patent describes an improved gas leak detection apparatus for detecting a leak in a gas containing vessel of constant volume. The entire disclosure of U.S. Pat. No. 5,428,985 is hereby incorporated by reference as if being set forth in its entirety herein. The apparatus described therein compensates for deviations in the behavior of a contained gas from an ideal model. The apparatus incorporates a pressure transducer, an amplifier and feed back to effectively and accurately model the Van der Waal's equation for a given stored gas. The described apparatus is adaptable for operation with a number of different gases by changing circuit elements. The output of the apparatus is proportional to the total number of moles of gas present in the containment vessel at any particular time. As is well known, a mole equals 6×10²³ molecules of a substance. This number of moles may be indicative of a leak from the vessel upon a realization that a reduction in the number of moles of the mass of the gas of the vessel has occurred (absent an intentional reduction).

The above-identified U.S. Pat. No. 5,428,985, along with U.S. Pat. No. 4,766,763 entitled, “Gas Leak Detection Apparatus and Methods” issued to A. D. Kurtz on Aug. 30, 1988, further indicate problems and drawbacks of devices that operate according to the ideal gas law. The entire disclosure of U.S. Pat. No. 4,766,763 is also hereby incorporated by reference as if being set forth in its entirety herein.

According to an aspect of the present invention, a reliable device utilizing the Van der Waal's equation for reliably determining gas density over a wide range of pressures and temperatures may be provided. A gas density transducer utilizing a pressure transducer in conjunction with and under control of an internal microprocessor, to provide reliable and accurate outputs indicative of gas density, may also be provided.

A gas density transducer according to an aspect of the present invention measures the pressure and temperature of the gas, and from these parameters calculates the gas density, using some gas specific constants, stored in a memory. The memory may be internal or external to the transducer. As used herein, “memory” refers to one or more devices capable of storing data, such as in the form of chips, tapes or disks. Memory may take the form of one or more random-access memory (RAM), read-only memory (ROM), programmable read-only memory (PROM), erasable programmable read-only memory (EPROM), or electrically erasable programmable read-only memory (EEPROM) chips, by way of further non-limiting example only.

According to an aspect of the present invention, the calculation may include using the Perfect Gas Equation: pV=nRT, where: p=pressure, T=absolute pressure, n=number of moles, V=volume, R=perfect gas constant. By measuring p and V, and knowing R, the gas density may be calculated in terms of moles/liter using the equation:

$$\frac{n}{V} = \frac{1}{R} * \frac{p}{T} ,$$

where n/V is the gas density, in moles/liter.

This relation may be well suited for low gas densities, i.e., low pressures, up to about 300 pounds per square inch absolute (psia). Above this pressure, using this equation may produce significant errors.

For higher pressures and high gas densities, the same gas density n/V in moles/liters can be calculated using the Van der Waal's equation:

$$( p + a * \frac{{n}^{2}}{{V}^{2}} ) ( V - bn ) = nRT ,$$

where a and b are gas specific coefficients. These coefficients provide for corrections due to the non-zero volume of the molecules of gas (b) and the inter-molecular forces (a). The Van der Waal's equation is a widely used formula, universally accepted, and consistently verified by experimental measurements. A major advantage of the Van der Waal's formula versus the Perfect Gas Equation is that it maintains its validity and accuracy over a wider range of pressures and temperatures.

By dividing both sides of the Van der Waal's equation by V one may obtain:

$$( p + a * \frac{{n}^{2}}{{V}^{2}} ) * ( 1 - b * \frac{n}{V} ) = \frac{n}{V} * R * T ,$$

from where n/V can be determined. The molar gas density n/V may be converted to more practical units, like grams/liter or ounces/gallon by multiplying n/V with the molecular mass of the gas.

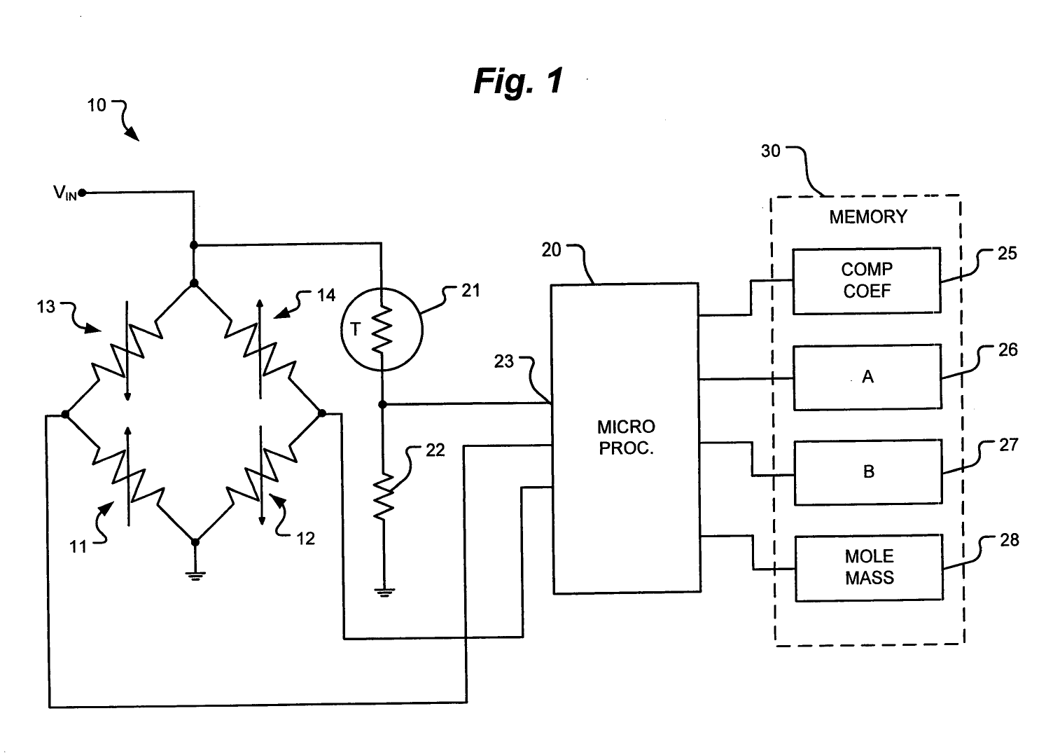

Referring now to FIG. 1, there is shown a schematic diagram of a pressure transducer 10 having a bridge configuration having piezoresistive elements 11, 12, 13 and 14 arranged in a Wheatstone Bridge configuration. The output of the piezoresistive bridge configuration, or bridge, is directed to the inputs of a microprocessor 20, which operates to process the bridge signal to produce an output indicative of gas density. There is also shown a temperature sensor 21. In an exemplary configuration, sensor 21 may take the form of temperature dependent resistive device, like a resistance temperature detector (RTD). For non-limiting purposes of further explanation only, RTDs use metals whose resistance increases with temperature. The resistivity of sensor 21 may increase linearly with temperature over a given range, and be related to the dimensions of the metal element thereof, such as length and cross-sectional area. According to an aspect of the present invention, sensor 21 may take the form of a semiconductor sensor or any other well known device which is responsive to temperature as well.

Referring still to FIG. 1, temperature sensor 21 is coupled in series with a resistor 22 between bridge input VIN and ground, with a terminal junction between the sensor 21 and resistor 22 also directed to an input 23 of the microprocessor 20. Input 23 may be a real-time, or substantially real-time input. Therefore, the microprocessor 20 receives an input, such as a voltage, indicative of temperature and also an input indicative of pressure.

In one configuration, the bridge and temperature sensor may both be positioned or mounted in or on a container, tank or other environment, where the gas density is to be monitored.

According to an aspect of the present invention, microprocessor 20 may include memory 30 that stores a composition coefficient in a memory portion 25. Memory 30 may also store alpha (a) and beta (b) coefficients in memory portions 26 and 27, indicative of the coefficients specific to a particular gas, as indicated above for the Van der Waal equation. Memory 30 may also store, in a portion 28, values indicative of the molecular mass of the specific gas. Alternatively, memory 30, or one or more portions thereof, may be external to, but accessible by processor 20.

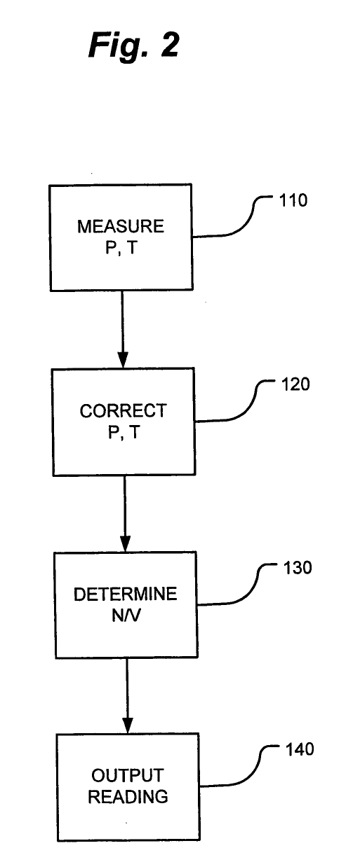

Referring now also to FIG. 2, there is shown a block diagrammatic representation of a process 100 being suitable for use with the transducer of FIG. 1. Process 100 may be executed in conjunction with or by microprocessor 20 using memory 30. First, a measurement of the raw output of the pressure sensor bridge 10 and the temperature sensor 21 is taken 110. Optionally, the bridge itself may take the form of a temperature compensated bridge, such as that shown in U.S. Pat. No. 6,700,473, entitled PRESSURE TRANSDUCER EMPLOYING ON-CHIP RESISTOR COMPENSATION, or U.S. Pat. No. 5,686,826, entitled AMBIENT TEMPERATURE COMPENSATION FOR SEMICONDUCTOR TRANSDUCER STRUCTURES, the entire disclosures of which are each also hereby incorporated by reference as if being set forth in their respective entireties herein. For example, bridge 10 may include one or more span-temperature compensating resistors. The temperature of the pressure sensor bridge may then be determined by measuring the resistance of the bridge, or span resistor, which changes in a predictable way with temperature. By measuring the resistance, the temperature that the bridge is subject to is derivable by microprocessor 20.

According to an aspect of the present invention, the pressure and temperature data acquired from bridge 10 in step 110 may be corrected 120. Microprocessor 20 corrects the raw measurements to determine the pressure and temperature of the bridge with good accuracy. By way of non-limiting example, the correction may be based on the measured resistance of the bridge or span-temperature compensating resistor, and/or the output of RTD 21, using compensation coefficients stored in the memory portion 25 and a polynomial interpolation algorithm. These coefficients may be determined by individually testing the transducer for a wide range of temperatures and pressures. The determined correction coefficients may be stored in memory 25, for retrieval by microprocessor 20 during step 120. Thus, the determined bridge temperature may be correlated with correction coefficients stored in memory 30, which correlated coefficients are then utilized to correct the transducer output.

The gas density (n/V) may then be determined 130 using Van der Waal's equation. The coefficients a and b, as well as the molecular mass of the gas, may also be retrieved from memory portions 26, 27 and 28 by microprocessor 20 for use thereby.

The actual solving of the equation may be accomplished using an iterative process and microprocessor 20. In this process, an initial estimated value for n/V, whereby this value changes until a best approximation is reached, may be used. Such a method may be well suited for use, as the Van der Waal equation is a third order type, with no simple and explicit solution. An analog and/or digital output may then be provided 140 by microprocessor 20 based on the solution reached at step 130.

Based on the algorithm described above, one can determine the gas density with good accuracy. For oxygen and nitrogen, and for pressures up to 5000 psia, and for a temperature range between −55° C. and +125° C., the accuracy of the gas density measurement may be better than ±0.25% of full scale. Such accuracy may result from good pressure and temperature measurements, ±0.1% of full scale for pressure and ±0.5° C. for temperature.

According to an aspect of the present invention, such a transducer output may be indicative of the time left for usage of a gas tank based on the determined quantity of gas and a known consumption rate. Such calculations may be performed by microprocessor 20 or other computational device(s) using conventional methodologies. The following program code, i.e., sequence of computer executable instructions, illustrates a programmed sequence to perform the various steps indicated above, including the storing of the coefficients and so on, according to one, non-limiting, embodiment of the present invention. The program is in source code and embodies an aspect of the present invention. The computer program code is loaded into and executed by a processor such as microprocessor 20, or may be referenced by a processor that is otherwise programmed, so as to constrain operations of the processor and/or other peripheral elements that cooperate with the processor. When such programming is executed by a suitable computing device, such as microprocessor 20, the processor or computer becomes an apparatus that practices an embodiment of a method of the present invention. When so implemented on a general-purpose processor, the computer program code segments configure the processor to virtually create specific logic circuits. Variations in the nature of the program carrying medium, and in the different configurations by which computational and control and switching elements can be coupled operationally, are all within the scope of the present invention disclosed herein.

/*******************************************************\;

| ; | Project | - WVW | : |
|---|---|---|---|
| ; | Company: | - Kulite Semiconductor | : |
| | | Products, Inc. | |
| ; | FileName | - WVW. hex | : |
| ; | ProjectFileName | - WVW.pjt | : |

:

\*******************************************************/
#include <pic.h>
#include “wvw.h”
/**** Globals ****/

| | |
|---|---|
| unsigned char Mode; | // @ 0023 |
| unsigned char AddrH; | // @ 0020 |
| unsigned char AddrL; | // @ 0021 |

| | |
|---|---|
| // | for(I=1;(OutBuf[I]=IntReadEEpromByte(j))!= ‘\0’;I++) j++; |

OutBuf[0] = ‘*’;
Write485(OutBuf,I,1);//−1

| } | |
|---|---|
| else if((CommandCount > 3) && (Mode == 1 )) | //Set data to value |

specfied

{

for(I = 0;I<17;I++)

OutBuf[I] = 0xff;

for(I = 0; I<Size; I++)

OutBuf[I] = Command485[I+4];

OutBuf[I] = ‘\0’;
IntWriteEEprom(Address, OutBuf, I+1);

}

}
int HexConvert(char c)
{

if(c >= ‘A’ && c <= ‘F’)
return (int)(c − 0x41 + 10);
if(c >= ‘0’ && c <= ‘9’)
return ((int)(c−‘0’));
return 0;

}

It will be apparent to those skilled in the art that various modifications and variations may be made in the apparatus and process of the present invention without departing from the spirit or scope of the invention. Thus, it is intended that the present invention cover the modification and variations of this invention provided they come within the scope of the appended claims and their equivalents.

What is claimed is:

1. A gas density transducer comprising:
a piezoresistive bridge sensor operative to provide an output indicative of an applied pressure,
a computing processor having multiple inputs and at least one output, with the output of the bridge sensor coupled to an input of the processor;
a temperature sensor coupled to an input of said processor for providing at an output a signal indicative of a temperature of said bridge sensor, said output of said temperature sensor coupled to an input of said processor; and,
at least one memory accessible by the processor and having stored therein:
compensation coefficients for compensating the output of said bridge sensor for temperature variation;
gas specific coefficients of the Van der Waal's equation; and,
code for providing at an output of said processor a signal indicative of a gas density when said bridge is subjected to a gas containing environment.

2. The gas density transducer of claim 1, wherein said at least one memory further stores values indicative of a molecular mass of at least one gas.

3. The gas density transducer of claim 1, wherein said piezoresistive bridge sensor is configured as a Wheatstone bridge.

4. The gas density transducer of claim 1, wherein said temperature sensor is an RTD.

5. The gas density transducer of claim 1, wherein the code for providing an output comprises code indicative of the equation:
$$( p + a * \frac{{n}^{2}}{{V}^{2}} ) * ( V - b * n ) = n * R * T ,$$
where p represents the pressure output of said bridge; a and b are gas specific constants; T represents the temperature of said temperature sensor; n represents the number of moles of gas; V represents volume; and R represents the perfect gas constant.

6. The gas density transducer of claim 1, wherein said memory further stores code for determining a reduction in measured quantities of gas.

7. The gas density transducer of claim 1, wherein said processor and memory are integrated into a microprocessor.

8. The gas density transducer of claim 1, wherein said memory further stores data indicative of a container.

9. The gas density transducer of claim 1, wherein said bridge and temperature sensor are co-excited by a common source in operation.

10. The gas density transducer of claim 1, wherein said output of said processor is proportional to said gas density.

11. The gas density transducer of claim 10, wherein said bridge sensor is temperature compensated.

12. A method for providing an output indicative of an amount of gas remaining in a container comprising:
receiving a first signal being indicative of a gas pressure;
receiving a second signal being indicative of a gas temperature;
retrieving compensation coefficients and gas specific coefficients of the Van der Waal's equation;
correcting said first signal using said retrieved compensation coefficients; and,
determining a gas density using said corrected first signal, second signal and retrieved gas specific coefficients.

13. The method of claim 11, wherein said correcting is dependent upon said second signal.

14. The method of claim 11, further comprising retrieving data indicative of a molecular mass of at least one gas.

15. The method of claim 11, wherein said determining comprises an iterative process associated with the equation:
$$( p + a * \frac{{n}^{2}}{{V}^{2}} ) * ( V - b * n ) = n * R * T ,$$
where p represents the pressure output of said bridge; a and b are gas specific constants; T represents the temperature of said temperature sensor; n represents the number of moles of gas; V represents volume; and R represents the perfect gas constant.

16. The method of claim 11, further comprising determining a reduction in measured quantities of gas.

17. The method of claim 11, further comprising retrieving data indicative of an internal volume of the container.

18. The method of claim 11, further comprising providing an output proportional to said gas density.
